(19) United States
(12) Patent Application Publication
(10) Pub. No.: US 2009/0134922 A1
(43) Pub. Date: May 28, 2009

(54) Start-up circuit for bias circuit

(76) Inventor: Cheng-Hung Chen, Jhubei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/987,032

(22) Filed: Nov. 27, 2007

(51) Int. Cl. H03L 7/00

(52) U.S. Cl. 327/143

(57) ABSTRACT

A start-up circuit for a bias circuit is disclosed. The start-up circuit uses a switch to provide an activating signal to pull the bias circuit out of the null mode. The switch is triggered by a pulse from an external pulse supply or a combined pulse generator. After the pulse, the bias circuit enters a steady operational state and the start-up circuit stops operating. Therefore the start-up circuit has advantages of wide supply range, no standby current, short start-up time and simple circuit topology.

### FIELD OF THE INVENTION

This invention relates to a start-up circuit, more especially, which does not consume the standby current and can be applied to a wide range of supply voltage.

### BACKGROUND OF THE RELATED ART

A start-up circuit is used to pull a bias circuit out of the null state to a steady operational state to activate an electronical device, wherein the null state is also called zero-current state. The demands of a start-up circuit ideally include no standby current, simple circuit design, large supply range and short start-up time.

A bias circuit is described as the following and shown in FIG. 1. The bias circuit 100 is connected to a voltage source with voltage V_{CC} and the ground. The bias circuit includes a left leg and a right leg to form a current-mirror-based bias circuit. The left leg includes a p-channel metal oxide silicon field effect transistor (PMOS) MP₁ and an n-channel metal oxide silicon field effect transistor (NMOS) MN₁. The right leg includes the corresponding PMOS MP₂, NMOS MN₂, and a bias resistor R_{bias}. The gate and drain electrodes of the NMOS MN₁ are coupled at node V to form a diode connected NMOS, and the gate and drain electrodes of the PMOS MP₂ are coupled at node P to form a diode connected PMOS. The gate electrodes of the PMOS MP₂ and PMOS MP₁ are coupled, and the gate electrodes of the NMOS MN₁ and NMOS MN₂ are coupled also.

When a start-up voltage is provided at the node V to drive the NMOS MN₁ of the left leg, a current will be induced on the right leg to turn on the NMOS MN₂ and to pull the voltage on the node P down to turn on the PMOS MP₂ and PMOS MP₁. And, as the result, the bias circuit enters a steady operational state. The start-up voltage is provided by the start-up circuit, and the start-up circuit should be turned off when the bias circuit has entered the steady operational state. As supply voltage drops, some start-up circuits will not conduct a same current as at high supply, and that will increase the start-up time.

A lot of start-up circuits have been proposed, but some can not satisfy the demands of large supply rang or no standby current and some can not satisfy the demands of short start-up time or simple circuit topology. This invention provides a new start-up circuit for the bias circuit, which has the advantages of no standby current, simple circuit topology, short start-up time and wide supply range.

### SUMMARY OF THE INVENTION

It is an object of this invention to provide a start-up circuit for driving a bias circuit from a null state to a steady operational state. The start-up circuit uses a switch coupled to the bias circuit, and, once the switch receives a voltage pulse, the switch will send out activating signals to activate the bias circuit. The switch uses a pulse generator or connects to a pulse supply, which receives an enable voltage and transforms the enable voltage to a voltage pulse for providing the switch with the pulse/pulses.

### BRIEF DESCRIPTION OF THE DRAWINGS

FIG. 1 is a diagram showing a bias circuit according to a prior art.

FIG. 2 and FIG. 3 are schematic diagrams showing the basic electrical circuit according to an embodiment of this invention.

FIG. 4a and FIG. 4b are diagrams showing the circuits of pulse generators according to different embodiments of this invention.

FIG. 5a and FIG. 5b are diagrams showing the circuits of switches, corresponding to the pulse generators shown in FIG. 4a and FIG. 4b, respectively, according to different embodiments of this invention.

### DETAILED DESCRIPTION OF THE INVENTION

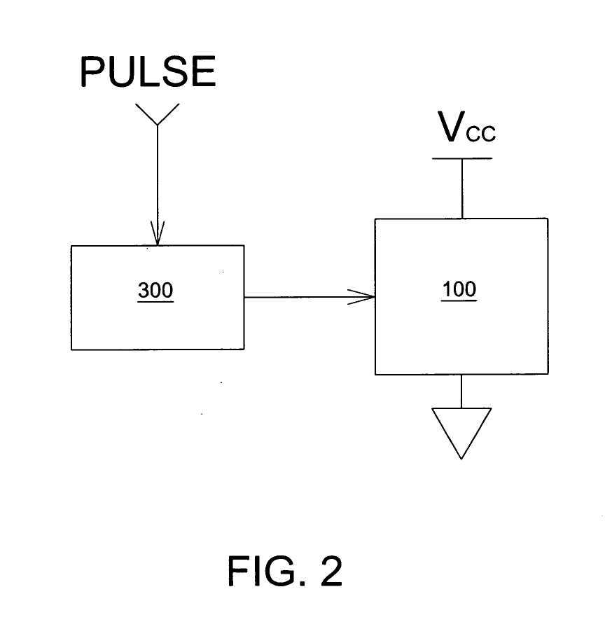

FIG. 2 shows a schematic diagram of a start-up circuit to bias circuit. As shown in figure, the start-up circuit includes a switch 300 coupled to the bias circuit 100. The switch 300 receives a pulse, which is marked as the “PULSE” in the figure. For example, the pulse is from a pulse supply. The pulse will turn on the switch 300, and the switch will send out an activating signal for activating the bias circuit 100. After the pulse, the switch 300 is turned off to stop operation of the start-up circuit.

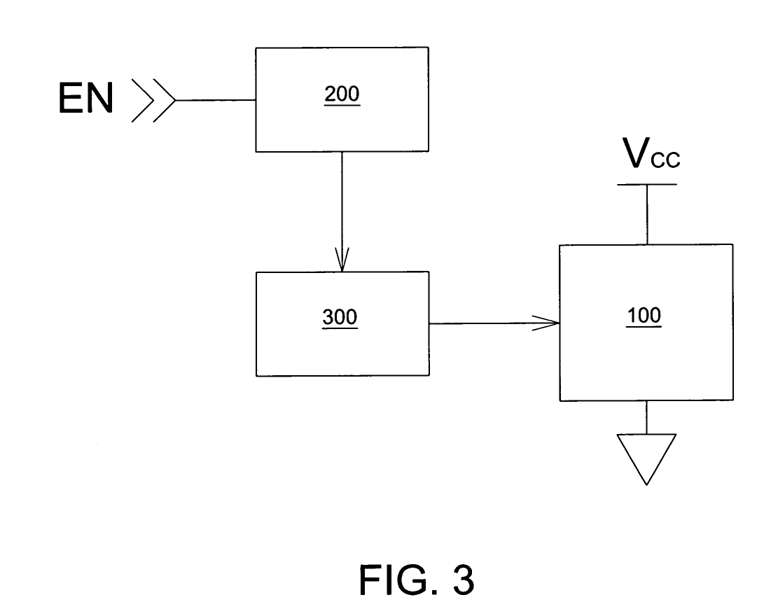

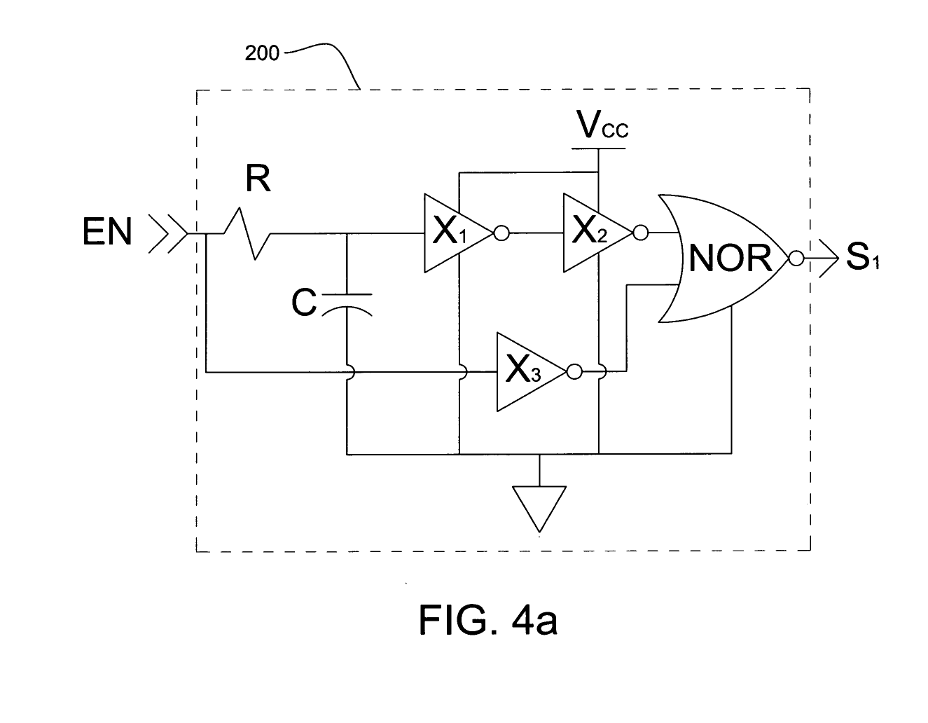

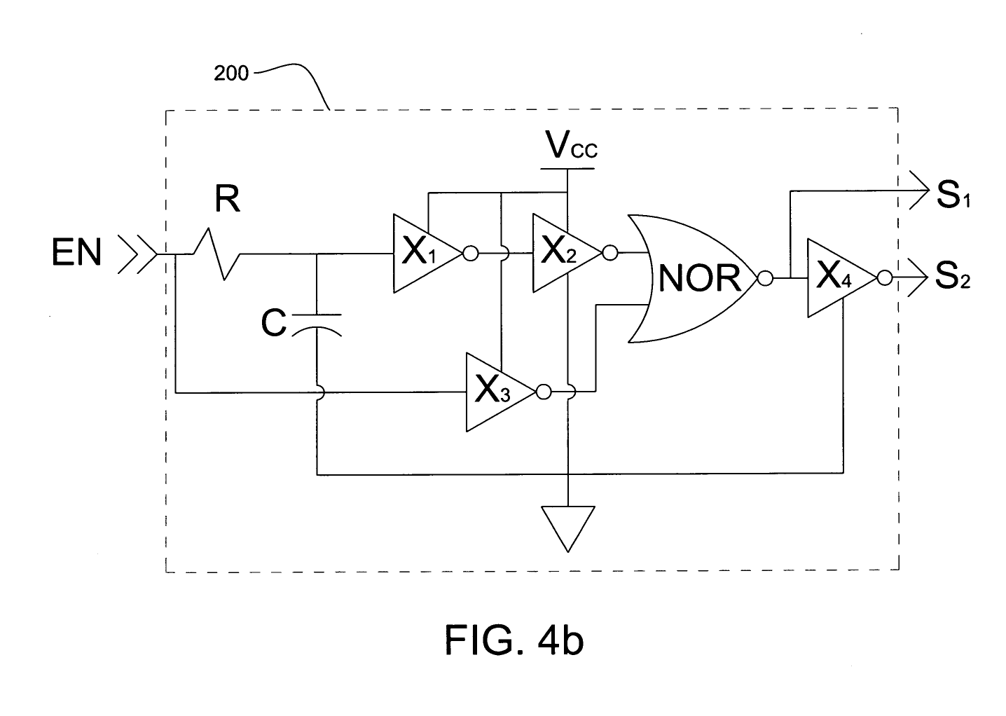

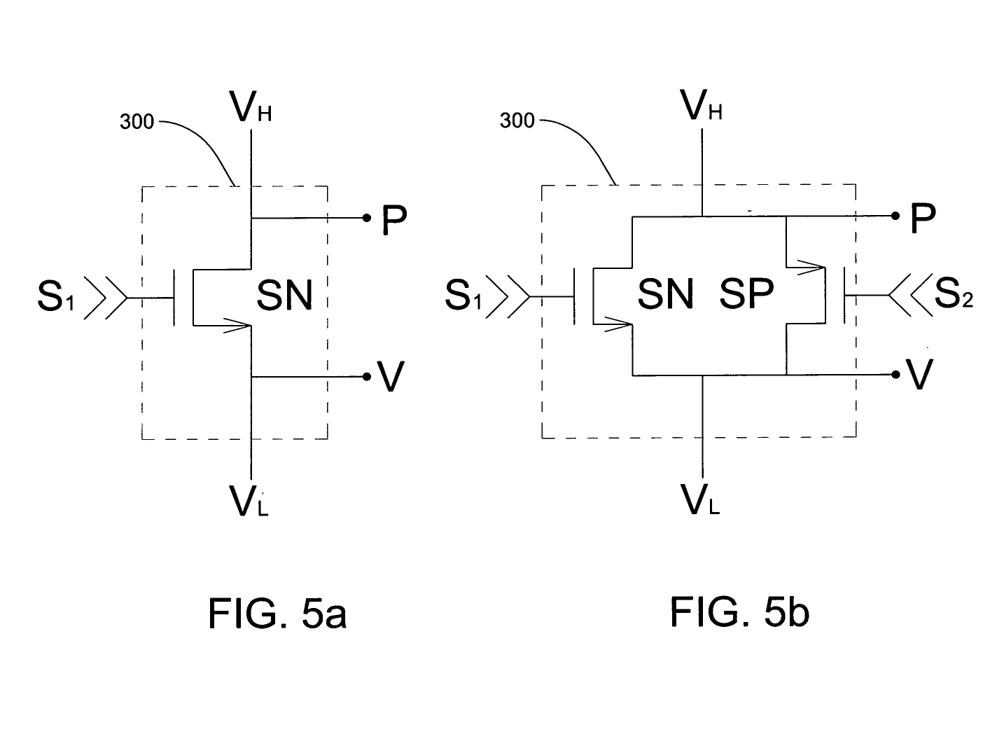

An exemplary embodiment is provided as shown in FIG. 3, which shows a schematic diagram of the connection of a start-up circuit and a bias circuit 100. The start-up circuit includes a pulse generator 200 and a switch 300. The pulse generator 200 receives an enable voltage, which is shown as EN in FIG. 3, and then sends out at least a pulse voltage to control the switch 300. Different embodiments of the pulse generator 200 are shown in FIG. 4a and FIG. 4b, and different embodiments of the switch 300 are shown in FIG. 5a and FIG. 5b.

An exemplary embodiment of a pulse generator is shown as FIG. 4a, The pulse generator includes a resister R, a capacitor C, three NOT gates X₁, X₂, X₃ (NOT gate is called inverter also.) and a NOR gate, which does a logical computation of “not or” and is marked NOR in figures. The output end of resister R connects the capacitor C to form a RC circuit, which can delay the enable voltage EN with a period and then forms a voltage with a step waveform. The other end of the capacitor C is connected to the ground, and the other end of the resister R, called input end of the resister, receives the enable voltage EN. The first NOT gate X₁ and the second NOT gate X₂ are connected in series, and then connected between the output end of the resister R and one input of the NOR gate. The serial-connected NOT gates X₁, X₂ can sharpen the step-waveformed voltage, which is the first step-waveformed voltage.

The third NOT gate X₃ is connected to the input end of the resister, and the output is connected to the other input of the NOR gate. The third NOT gate X₃ provides a second step-waveformed voltage with an inverse phase to the first step-waveformed voltage. After logical computation of the NOR gate, a voltage pulse S₁ is produced on its output end. The voltage pulse is shown as S₁ in FIG. 4a.

The difference between the front edges of the waveforms of the first step-waveformed voltage and the second step-waveformed voltage is the width of the pulse voltage S₁, which is also called duty time of pulse voltage S₁. The width of the pulse voltage S₁ should be minimized but long enough to activate the bias circuit. The optimal width can be obtained by tuning the resister R and the capacitor C. Therefore, the current consumption and the start-up time are reduced to the minimum.

Another exemplary embodiment of the pulse generator 200 is shown as the FIG. 4b. Comparing this embodiment with that shown in FIG. 4a, a fourth NOT gate X₄ is connected to the output of the NOR gate. The fourth NOT gate sends out another pulse voltage S₂ with an inverse phase respective to the pulse voltage S₁. The pulse voltages S₁, S₂ are marked as S₁, S₂ in FIG. 4b.

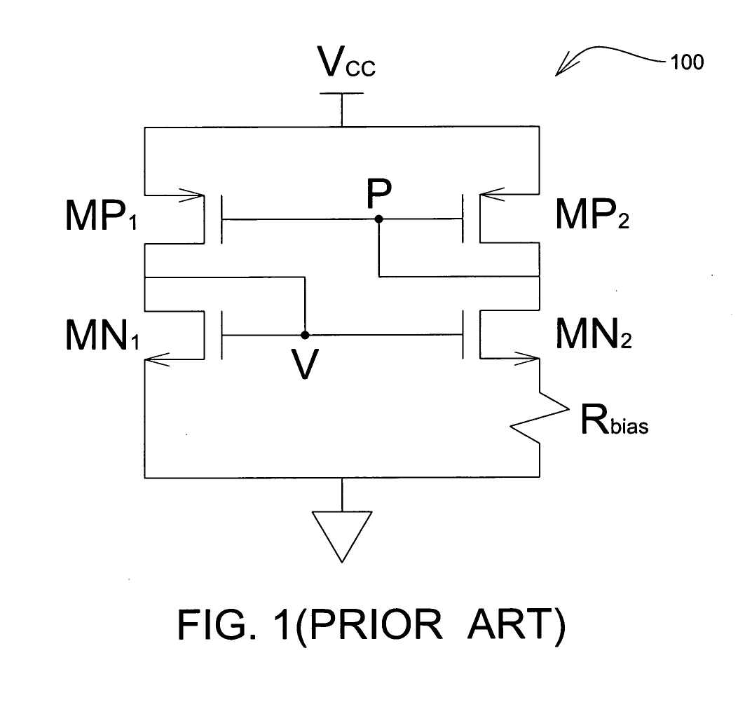

In figures FIG. 5a and FIG. 5b, P and V represent the coupling points of a switch to the bias circuit. When the coupling point P of the switch is coupled to the node P of the bias circuit in FIG. 1, the coupling point V of the switch can be coupled to the node V of the bias circuit in FIG. 1 or an external connection end with a voltage V_{L}, and the voltage V_{L} is smaller than the voltage on the coupling point P. For example, the coupling point V of the switch is connected to the ground. Or, when the coupling point V of the switch is coupled to the node V of the bias circuit in FIG. 1, the coupling point P of the switch can be coupled to the node P of the bias circuit in FIG. 1 or an external connection end with a voltage V_{H}, and the voltage V_{H} is higher than the voltage on the coupling point V, for example, to the power supply with voltage V_{CC}.

An exemplary embodiment of a switch 300 shown in FIG. 5a is designed to cooperate with the pulse generator 200 in FIG. 4a. The switch includes an n-channel metal oxide silicon field effect transistor, NMOS, marked as SN. The gate electrode of the NMOS SN is connected to the output of the NOR gate to receive the voltage pulse S₁, and the drain electrode and the source electrode are the coupling points P, V.

The operation method is explained as the following. Once the voltage pulse S₁ is received, the NMOS SN is turned on, and the coupling points P, V will send out the activating signals to activate the bias circuit. After pulse voltage S₁, the switch is turned off to stop the operation of the start-up circuit, and, as the result, the standby current will be eliminated.

Another switch 300 shown in FIG. 5b is designed to cooperate with the pulse generator 300 in FIG. 4b. The switch includes a p-channel metal oxide silicon field effect transistor, PMOS SP, and an NMOS SN. The gate of the PMOS SP is connected to the output of the fourth NOT gate X₄ to receive the voltage pulse S₂, and the gate of NMOS SN to the output of the NOR gate to receive the voltage pulse S₁. The drain electrode of the NMOS SN is coupled to the source electrode of the PMOS, and the source electrode of the NMOS SN is coupled to the drain electrode of the PMOS SP. And, then, the source electrode and the drain electrode of the PMOS SP are the coupling points P, V, respectively.

In this embodiment, the NMOS SN can provide a lower activating voltage and the PMOS SP can provide a higher activating voltage, and therefore the switch can provide a large range of the activating voltage. Accordingly, the NMOS SN can be omitted if only the higher activating voltage is needed, or PMOS SP can be omitted for lower activating voltage only.

For this invention can be understood better, here the switch is combined to the pulse generator, but should not be limited by the pulse generator. It can be understood that the start-up circuit can be constructed by a switch and an external pulse supply, or the switch having a pulse generator, such as the embodiments as abovementioned. And, the switch is driven by the pulse/pulses from the pulse supply or the pulse generator.

According to the abovementioned embodiments, the switch is controlled by a pulse supply or a pulse generator, so the start-up circuit is not limited by the supply. Therefore, a wide supply range is attained.

Although the present invention has been explained in relation to its preferred embodiment, it is to be understood that modifications and variation can be made without departing the spirit and scope of the invention as claimed.

What is claimed is:

1. A start-up circuit, applied to a bias circuit, comprising:
a pulse supply configured to receive an enable voltage and transmit at least a pulse; and
a switch coupled to said pulse generator and said bias circuit in order to transform said pulse/pulses from said pulse supply to an activating signal for driving said bias circuit.

2. A start-up circuit according to claim 1, wherein said switch comprises an NMOS, and the gate electrode of said NMOS is configured to receive the pulse/pulses from said pulse supply, and there is a voltage deference between said source electrode and the drain electrode.

3. A start-up circuit according to claim 1, wherein said switch comprises a PMOS, and the gate electrode of said PMOS is configured to receive the pulse/pulses from said pulse supply, and there is a voltage difference between said source electrode and the drain electrode.

4. A start-up circuit according to claim 1, wherein said switch comprises an NMOS and a PMOS, and the gate electrodes of said NMOS and said PMOS are configured to receive pulses from said pulse supply, and the source electrode of said PMOS is coupled to the drain source of said NMOS, and the drain electrode of said PMOS is coupled to the source electrode of said NMOS, and there is a voltage deference between the source electrode and the drain electrode of said NMOS or said PMOS.

5. A start-up circuit according to claim 1, wherein said pulse supply is a pulse generator.

6. A start-up circuit according to claim 5, wherein said pulse generator comprises:
a resister and a capacitor, wherein one end of said capacitor is connected to an output end of said resister and the other end to the ground, and an input of said resister is configured to receive said enable voltage;
a NOR gate, wherein an output of said NOR gate is configured to send out a pulse;
a first NOT gate and a second NOT gate connected in series, wherein an input of said first NOT gate is connected to the output end of said resister and an output of said second NOT gate is connected to one input of said NOR gate; and
a third NOT gate, wherein an input of said third NOT gate is connected to the input end of said resister, and an output of said third NOT gate is connected to the other input of said NOR gate.

7. A start-up circuit according to claim 6, wherein said switch comprises an NMOS, and the gate electrode of said NMOS is connected to the output of said NOR gate, and there is a voltage difference between the source electrode and the drain electrode of said NMOS, and the source electrode or the drain electrode of said NMOS can be coupled to said bias circuit.

8. A start-up circuit according to claim 6, wherein said pulse generator further comprises a fourth NOT gate, and an input of said fourth NOT gate is connected to the output of said NOR gate, and the output of said fourth NOT gate transmits another pulse with an inverse phase to the pulse from said NOR gate.

9. A start-up circuit according to claim 8, wherein said switch comprises a PMOS, and the gate electrode is connected to the output of said fourth NOT gate, and there is a voltage difference between the source electrode and the drain electrode of said PMOS, and the source electrode or the drain electrode of said PMOS can be coupled to said bias circuit.

10. A start-up circuit according to claim 9, wherein said switch further comprises an NMOS, and the gate electrode of said NMOS is connected to the output of said NOR gate, and the source electrode and the drain electrode of said NMOS are coupled to the drain electrode and the source electrode of said PMOS, respectively.

11. A start-up circuit according to claim 8, wherein said switch comprises an NMOS, and the gate electrode of said NMOS is connected to output of said NOR gate, and there is a voltage difference between the source electrode and the drain electrode of said NMOS, and the source electrode or the drain electrode of said NMOS can be coupled to said bias circuit.
